(19) United States
(12) Patent Application Publication
(10) Pub. No.: US 2009/0029557 A1
(43) Pub. Date: Jan. 29, 2009

(54) PLASMA ETCHING METHOD, PLASMA ETCHING APPARATUS AND STORAGE MEDIUM

(75) Inventors: Akihiro Kikuchi, Nirasaki-shi (JP); Kenji Idehara, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/180,012

(22) Filed: Jul. 25, 2008

Related U.S. Application Data
(60) Provisional application No. 60/982,752, filed on Oct. 26, 2007.

(30) Foreign Application Priority Data
Jul. 27, 2007 (JP) 2007-195734

(51) Int. Cl. H01L 21/302

(52) U.S. Cl. 438/714; 156/345.34; 257/E21.214

(57) ABSTRACT

A plasma etching method plasma-etches an etching target film by using a photoresist film as a mask. The plasma etching method includes loading a target object to be processed into a processing chamber where an upper and a lower electrode are provided to face each other, the target object having the etching target film and the photoresist film in which an opening is formed; introducing into the processing chamber a processing gas containing CF₄ gas, CH₂F₂ gas and CₓF_{y} gas, wherein x/y≧0.5; and generating a plasma of the processing gas by applying a high frequency power to at least one of the upper and the lower electrode. The method further includes, by the plasma, etching the etching target film introduced through the opening formed in the photoresist film while reducing the opening size the opening.

### FIELD OF THE INVENTION

The present invention relates to a method and an apparatus for performing plasma etching on a predetermined film of a target object, e.g., a semiconductor substrate and the like, by using as a mask a photoresist film, e.g., an ArF resist film or the like, and a storage medium storing a program for executing the plasma etching method.

### BACKGROUND OF THE INVENTION

In a semiconductor device manufacturing process, a photolithography process is performed to form a photoresist pattern on a semiconductor wafer as a target object, and an etching process is performed by using the photoresist pattern as a mask.

To match a recent progress in miniaturization of semiconductor devices, it becomes necessary to employ microprocessing in etching. To this end, in micro-etching, a thickness of a photoresist film used as a mask is getting thinner, and an ArF photoresist (i.e., a photoresist exposed to a laser beam having a shorter wavelength of which an emission source is an ArF gas) adequate for forming a pattern opening no greater than about 0.13 μm begins to be preferably employed therefor instead of a KrF photoresist (i.e., a photoresist exposed to a laser beam of which en emission source is a KrF gas).

However, in a conventional photolithography process using an ArF photoresist, it is difficult to form a finer hole due to its limitation in miniaturization. To that end, there can be employed a technique for depositing plasma reaction products on a sidewall of an ArF photoresist film as a mask layer (see, e.g., Japanese Patent Laid-open Publication No. 2005-129893 (JP-A-2005-129893)). Such a technique makes it possible to form a finer pattern by reducing an opening size of an opening formed in the photoresist film. Further, Japanese Patent Laid-open Publication No. 2006-269879 (JP-A-2006-269879) discloses a technique that modifies a gas supply method depending on types of CF-based gases because although active species of the CF-based gases serve to function in both etching and polymer deposition on a sidewall of a hole, their exact functions are changed depending on the types of the CF-based gases.

However, when the ArF photoresist is patterned by employing the photolithography, its surface state becomes deteriorated and, also, cracks are easily generated therein. Therefore, when the etching is performed by employing the technique of JP-A-2005-129893, although the opening size can be reduced, the cracks generated on the ArF photoresist film remain unrepaired. Accordingly, the amount of the residual ArF photoresist film is insufficient in the portions where the cracks are generated. As a consequence, base wiring patterns are damaged, and this may lead to a short-circuit. Besides, the technique of JP-A-2005-129893 is disadvantageous in that a long period of time is needed to reduce the opening size to a desired size, which deteriorates a throughput. Moreover, JP-A-2006-269879 discloses a technique for controlling the etching and the polymer deposition by the processing gas, but does not describe a technique for reducing the opening size and repairing the cracks formed in the ArF resist.

Meanwhile, when a supermicro pattern is formed, an antireflection film made of a material capable of absorbing light in a wavelength range of light used as an exposure light source is interposed between a film to be etched and a photoresist film. This is because a CD (critical dimension) of a photoresist pattern varies due to diffracted light and reflected light from an etching target film, standing waves and reflective notching generated by variation in a thickness of a photoresist film, and optical properties of the etching target film formed under a photoresist film. Recently, as for the antireflection film, an organic antireflection film is widely used. Further, when the organic antireflection film is etched, there is used the plasma etching using a photoresist film as a mask (see, e.g., Japanese Patent Laid-open Publication No. 2005-26348).

However, the organic anti-reflection film has a similar composition to that of the ArF photoresist film. Therefore, when the organic anti-reflection film is etched, the ArF photoresist film is etched at substantially the same etching rate. Accordingly, the amount of the residual mask film becomes insufficient.

### SUMMARY OF THE INVENTION

In view of the above, the present invention provides a plasma etching method and a plasma etching apparatus which are capable of performing etching while reducing an opening size of a photoresist pattern at a high etching rate and improving a surface state of a photoresist film by repairing cracks.

Further, the present invention provides a plasmas etching method and a plasma etching apparatus which are capable of etching an organic anti-reflection film with a high etching selectivity to a photoresist film.

In accordance with a first aspect of the invention, there is provided a plasma etching method for plasma etching an etching target film by using a photoresist film as a mask. The plasma etching method includes loading a target object to be processed into a processing chamber where an upper and a lower electrode are provided to face each other, the target object having the etching target film and the photoresist film in which an opening is formed; introducing into the processing chamber a processing gas containing CF₄ gas, CH₂F₂ gas and CₓF_{y} gas, wherein x/y≧0.5; and generating a plasma of the processing gas by applying a high frequency power to at least one of the upper and the lower electrode. The plasma etching method further includes, by the plasma, etching the etching target film through the opening formed in the photoresist film while reducing the opening size the opening.

In accordance with a second aspect of the invention, there is provided a plasma etching method for plasma etching an etching target film by using a photoresist film as a mask.

The plasma etching method includes loading a target object to be processed into a processing chamber where an upper and a lower electrode are provided to face each other, the target object having the etching target film and the photoresist film in which an opening is formed as an etching pattern; introducing into the processing chamber a processing gas containing CF₄ gas, CH₂F₂ gas and CₓF_{y} gas, wherein x/y≧0.5; generating a plasma of the processing gas by applying a high frequency power to at least one of the upper and the lower electrode; and applying a DC voltage to one of the upper and the lower electrode for a predetermined time period while the plasma is formed.

The plasma etching method further includes, by the plasma, etching the etching target film through the opening formed in the photoresist film while reducing the opening size of the opening.

In accordance with the second aspect, the DC voltage is preferably in the range from −500 V to −1500 V. Further, the CₓF_{y} gas may include at least one species selected from the group consisting of C₄F₈ gas, C₅F₈ gas and C4F6 gas. Further, the CₓF_{y} gas may be C₅F₈ gas, and a flow rate thereof is preferably in the range from 5 to 10 sccm. The target object may have an organic bottom anti-reflection coating film between the photoresist film and the etching target film.

In accordance with a third aspect of the invention, there is provided a plasma etching method for plasma-etching an organic bottom anti-reflection coating film and an etching target film by using a photoresist film as a mask in a target object to be processed which is manufactured by sequentially forming, on the etching target film, the organic bottom anti-reflection coating film and the photoresist film formed thereon with an opening therein.

The plasma etching method includes loading the target object into a processing chamber where an upper and a lower electrode are provided to face each other; introducing into the processing chamber a processing gas; generating a plasma of the processing gas by applying a high frequency power to at least one of the upper and the lower electrode; and applying a DC voltage to one of the upper and the lower electrode for a predetermined time period while the plasma is formed so that the organic bottom anti-reflection coating film is etched with a selectivity greater than or equal to a predetermined value to the photoresist film.

In accordance with the third aspect, the DC voltage is preferably in the range from −1000 V to −1500 V. Further, the processing gas may contain CF4 gas, CH2F2 gas, CxFy gas, wherein x/y≧0.5.

In accordance with a fourth aspect of the invention, there is provided a plasma etching method for plasma-etching an organic bottom anti-reflection coating film and an etching target film by using a photoresist film as a mask in a target object to be processed which is manufactured by sequentially forming, on the etching target film, the organic bottom anti-reflection coating film and the photoresist film formed thereon with an opening therein serving as an etching pattern.

The plasma etching method includes loading the target object into a processing chamber where an upper and a lower electrode are provided to horizontally face each other; introducing into the processing chamber a processing gas containing CF₄ gas, CH₂F₂ gas and CₓF_{y} gas, wherein x/y≧0.5; generating a plasma of the processing gas by applying a high frequency power to at least one of the upper and the lower electrode; applying a DC voltage to one of the upper and the lower electrode for a first time period while the plasma is formed so that the opening size of the opening formed in the photoresist film is reduced; and then applying a DC voltage to one of the upper and the lower electrode for a second time period while the plasma is formed so that the organic bottom anti-reflection coating film is etched with a selectivity greater than or equal to a predetermined value to the photoresist film.

In accordance with the fourth aspect, the DC voltage applied during the first time period is preferably in the range from −500 V to −1500 V, and the DC voltage applied during the second time period is preferably in the range from −1000 V to −1500 V. Further, the CₓF_{y} gas may include at least one species selected from the group consisting of C₄F₈ gas, C₅F₈ gas and C₄F₆ gas. Further, the CₓF_{y} gas may be C₅F₈ gas, and a flow rate thereof is preferably in the range from 5 to 10 sccm.

In accordance with a fifth aspect of the invention, there is provided a plasma etching apparatus including a vacuum-evacuable processing chamber having therein a target object to be processed having a photoresist film and an etching target film; an upper and a lower electrode disposed in the processing chamber to face each other; a gas introduction mechanism for introducing into the processing chamber a processing gas containing CF₄ gas, CH₂F₂ gas and CₓF_{y} gas, wherein x/y≧0.5; and a high frequency power supply unit for generating a plasma of the processing gas by applying a high frequency power to at least one of the upper and the lower electrode.

The plasma etching apparatus further includes a control unit for controlling at least one of the gas introduction mechanism and the high frequency power supply unit so that, by the plasma, an etching target film is etched through an opening formed in the photoresist film while reducing the opening size of the opening.

In accordance with a sixth aspect of the invention, there is provided a plasma etching apparatus including a vacuum-evacuable processing chamber having therein a target object to be processed; an upper and a lower electrode disposed in the processing chamber to face each other; a gas introduction mechanism for introducing into the processing chamber a processing gas containing CF₄ gas, CH₂F₂ gas and CₓF_{y} gas, wherein x/y≧0.5; and a high frequency power supply unit for generating a plasma of the processing gas by applying a high frequency power to at least one of the upper and the lower electrode.

The plasma etching apparatus further includes a DC power supply unit for applying a DC voltage to one of the upper and the lower electrode and a control unit for controlling the DC power supply unit, at least one of the gas introduction mechanism and the high frequency power supply unit so that, by the plasma, an etching target film is etched through an opening formed in the photoresist film while reducing the opening size of the opening.

In accordance with a seventh aspect of the invention, there is provided a plasma etching apparatus for plasma-etching an organic bottom anti-reflection coating film and an etching target film by using a photoresist film as a mask in a target object to be processed which is manufactured by sequentially forming, on the etching target film, the organic bottom anti-reflection coating film and the photoresist film thereon.

The plasma etching apparatus includes a vacuum-evacuable processing chamber having therein the target object; an upper and a lower electrode disposed in the processing chamber to face each other; a gas introduction mechanism for introducing a processing gas into the processing chamber; and a high frequency power supply unit for generating a plasma of the processing gas by applying a high frequency power to at least one of the upper and the lower electrode.

The plasma etching apparatus further includes a DC power supply unit for applying a DC voltage to one of the upper and the lower electrode and a control unit for controlling the DC power supply unit so that the organic bottom anti-reflection coating film is etched with a selectivity greater than or equal to a predetermined value to the photoresist film.

In accordance with an eighth aspect of the invention, there is provided a plasma etching apparatus for plasma-etching an organic bottom anti-reflection coating film and an etching target film by using a photoresist film as a mask in a target object to be processed which is manufactured by sequentially forming, on the etching target film, and the organic bottom anti-reflection coating film and the photoresist film thereon.

The plasma etching apparatus includes a vacuum-evacuable processing chamber having therein the target object; an upper and a lower electrode disposed in the processing chamber to face each other; a gas introduction mechanism for introducing into the processing chamber a processing gas containing CF₄ gas, CH₂F₂ gas and CₓF_{y} gas, wherein x/y≧0.5; and a high frequency power supply unit for generating a plasma of the processing gas by applying a high frequency power to at least one of the upper and the lower electrode.

The plasma etching apparatus further includes a DC power supply unit for applying a DC voltage to one of the upper and the lower electrode and a control unit for controlling the DC power supply unit to apply a DC voltage while plasma is formed such that while the plasma of the processing gas is generated by the high frequency power supply unit, there exists a specific time period during which the opening size of an opening formed in the photoresist film is reduced and a second time period during which the organic bottom anti-reflection coating film is etched with a selectivity greater than a predetermined value to the photoresist film.

In accordance with a ninth aspect of the invention, there is provided a storage medium storing therein a computer-executable program for controlling a plasma etching apparatus, wherein, when executed, the program controls the plasma etching apparatus to perform the plasma etching method described above.

In accordance with the aspects of the present invention, a processing gas containing CF₄ gas, CH₂F₂ gas, CₓF_{y} gas (x/y≧0.5) is used, and an etching target film is etched by using a plasma of the processing gas which is generated by applying a high frequency power to at least one of the first and the second electrode horizontally facing each other. Therefore, the effect of reducing an opening size by CF₄ gas and CH₂F₂ gas is facilitated by using CₓF_{y} gas. Accordingly, an opening size decreasing rate is increased, thus improving a throughput. Moreover, the surface of the ArF photoresist film can be planarized by CₓF_{y} gas. In addition, the thickness of the photoresist film can be increased, and the cracks can be repaired. Accordingly, a single layer resist can be used instead of a multi layer resist that has been conventionally used to avoid an insufficient amount of the residual ArF photoresist film. Moreover, the present invention is especially suitable for a technique used for forming a pattern of a narrow width, such as a double patterning technique or the like.

In accordance with the present invention, a processing gas containing CF₄ gas, CH₂F₂ gas, CₓF_{y} gas (x/y≧0.5) is used, and an etching target film is etched by using a plasma of the processing gas which is generated by applying a high frequency power to at least one of the first and the second electrode horizontally facing each other, as described above. In addition, by applying a DC voltage to any one of the first and the second electrode during the plasma generation, the polymers attached to the electrode to which the DC voltage is applied can be supplied to the target object. As a result, the above effects can be further enhanced.

In a target object manufactured by sequentially forming, on an etching target film, an organic antireflection film and a photoresist film thereon, when the plasma etching is performed on the organic antireflection film and the etching target film by using the photoresist film as a mask, a plasma of a processing gas is generated by applying a high frequency power to at least one of a first and a second electrode horizontally facing each other. In addition, by applying a DC voltage to any one of the first and the second electrode during the plasma generation, the polymers attached to the electrode to which the DC voltage is applied can be supplied to the target object. Consequently, the organic antireflection film can be etched with a high selectivity to the photoresist film.

In a target object manufactured by sequentially forming, on an etching target film, an organic antireflection film and a photoresist film thereon, when plasma etching is performed on the organic antireflection film and the etching target film by using the photoresist film as a mask, a processing gas containing CF₄ gas, CH₂F₂ gas, CₓF_{y} gas (x/y≧0.5) is used, and an etching target film is etched by using a plasma of the processing gas which is generated by applying a high frequency power to at least one of the first and the second electrode horizontally facing each other. In addition, a DC voltage is applied to any one of the first and the second electrode during the plasma generation. At this time, the plasma generation time period is divided into a first and a second time period. In the first time period, the DC voltage is set to reduce the opening size of the opening. In the second time period, the DC voltage is set to etch the organic antireflection film with a selectivity higher than a predetermined value to the photoresist film. Accordingly, it is possible to improve a throughput by increasing an opening size decreasing rate, planarize a surface of an ArF photoresist film and etch an organic anti-reflection film with a high selectivity to a photoresist film.

### BRIEF DESCRIPTION OF THE DRAWINGS

The objects and features of the present invention will become apparent from the following description of embodiments, given in conjunction with the accompanying drawings, in which:

FIG. 1 is a schematic cross sectional view of an example of a plasma etching apparatus used to perform embodiments of the present invention;

FIG. 2 illustrates a configuration of a matching unit connected to a first high frequency power supply of the plasma etching apparatus shown in FIG. 1;

FIG. 3 depicts a cross sectional view of a structure of a semiconductor wafer used in a first embodiment of the present invention;

FIG. 4 provides a cross sectional view showing a state where an opening size of an opening of a photoresist film is reduced in the semiconductor wafer illustrated in FIG. 3;

FIG. 5 is a cross sectional view depicting a state where plasma etching is performed by using as a mask the photoresist film having the reduced opening shown in FIG. 4;

FIG. 6 illustrates a variation in Vds and a plasma sheath thickness when a DC voltage is applied to an upper electrode in the plasma processing apparatus in FIG. 1;

FIG. 7 presents a scanning electron microscope picture showing a state of a photoresist film before etching a semiconductor wafer used for checking effects of the first embodiment;

FIG. 8 shows a scanning electron microscope picture illustrating a state of the photoresist film after the semiconductor wafer is etched under a condition of the first embodiment;

FIG. 9 offers a scanning electron microscope picture depicting a state of the photoresist film after the semiconductor wafer is etched under a comparative condition;

FIG. 10 shows a cross sectional view of a structure of a semiconductor wafer used in a second embodiment of the present invention;

FIG. 11 describes a relationship between a DC voltage applied to an upper electrode and an etching selectivity of an organic anti-reflection film to an ArF photoresist film;

FIG. 12 presents a schematic view of another example of the plasma etching apparatus applicable to the embodiments of the present invention;

FIG. 13 depicts a cross sectional view of still another example of the plasma etching apparatus applicable to the embodiments of the present invention;

FIG. 14 provides a schematic view of still another example of the plasma etching apparatus applicable to the embodiments of the present invention; and

FIG. 15 is a cross sectional view of still another example of the plasma etching apparatus applicable to the embodiments of the present invention.

### DETAILED DESCRIPTION OF THE EMBODIMENT

Hereinafter, embodiments of the present invention will be described with reference to the accompanying drawings which form a part hereof.

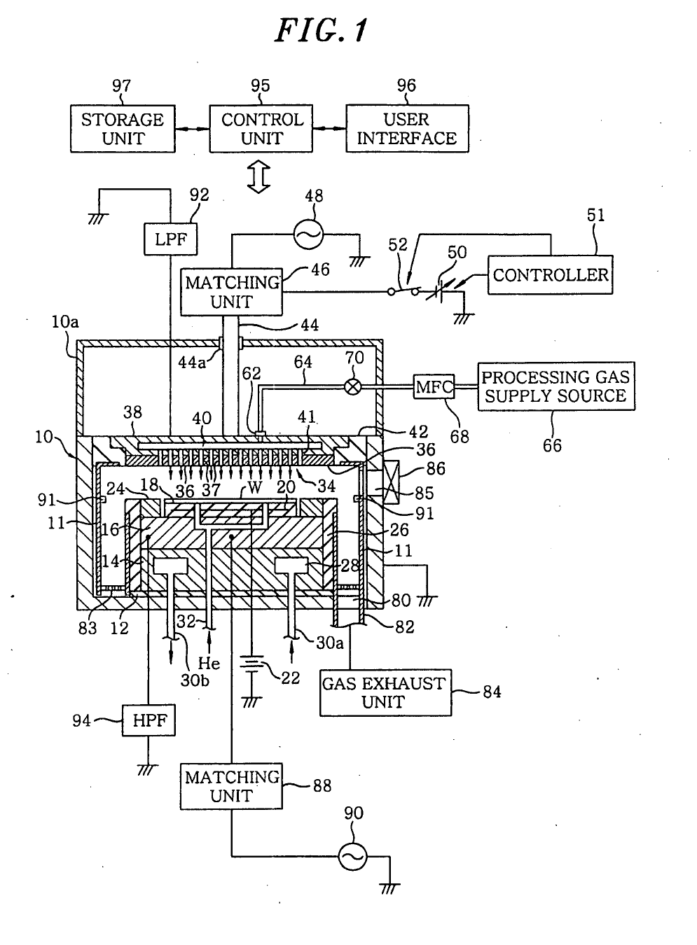

FIG. 1 is a schematic cross sectional view of an example of a plasma etching apparatus used to perform the embodiments of the present invention.

The plasma etching apparatus is configured as a capacitively coupled parallel plate type plasma etching apparatus having a substantially cylindrical chamber (processing vessel) 10 made of, e.g., aluminum of which a surface is anodically oxidized. The processing chamber 10 is frame grounded.

A columnar susceptor support 14 is disposed at a bottom portion of the chamber 10 via an insulating plate 12 made of ceramic or the like. Further, a susceptor 16 made of, e.g., aluminum is disposed on the susceptor support 14. The susceptor 16 serves as a lower electrode, while mounting thereon a substrate to be processed, e.g., a semiconductor wafer W.

Provided on top of the susceptor 16 is an electrostatic chuck 18 for attracting and holding the semiconductor wafer W with a help of an electrostatic force. The electrostatic chuck 18 is structured to have an electrode 20 made of a conductive film sandwiched between a pair of insulating layers or insulating sheets. A DC power supply 22 is connected to the electrode 20. The semiconductor wafer W is electrostatically attracted and held by the electrostatic chuck 18 with a help of the electrostatic force such as a Coulomb force generated by a DC voltage applied from the DC power supply 22.

Further, disposed on the periphery of the top surface of the susceptor 16 to surround the electrostatic chuck 18 (semiconductor wafer W) is a focus ring (calibration ring) 24 made of, e.g., silicon, for improving etching uniformity. A cylindrical inner wall member 26 made of, e.g., quartz is disposed on lateral surfaces of the susceptor 16 and the susceptor support 14.

A coolant passage 28 is provided inside the susceptor support 14 circumferentially, for example. A coolant, e.g., cooling water, of a specific temperature is supplied from a chiller unit (not shown) located at outside into the coolant passage 28 through lines 30a and 30b to be circulated therein, whereby a processing temperature of the semiconductor wafer W on the susceptor 16 can be controlled by controlling the temperature of the coolant.

Moreover, a thermally conductive gas, e.g., He gas, is supplied from a thermally conductive gas supply unit (not shown) into a space formed between the top surface of the electrostatic chuck 18 and the backside of the semiconductor wafer W through a gas supply line 32.

An upper electrode 34 is installed above the susceptor 16 serving as the lower electrode, to face the susceptor 16 in parallel. A space between the upper and lower electrodes 34, 16 becomes a plasma generation space. The upper electrode 34 forms a facing surface, i.e., a surface being in contact with the plasma generation space while facing the semiconductor wafer W on the susceptor 16.

The upper electrode 34 is held by an insulating shield 42 at a ceiling portion of the chamber 10. The upper electrode 34 includes an electrode plate 36 and an electrode support 38. The electrode plate 36 forms the facing surface to the susceptor 16 and is provided with a plurality of injection openings 37. The electrode support 38 holds the electrode plate 36 such that the electrode plate 36 can be detachably attached to the electrode support 38. The electrode support 38 of a water cooling type is made of a conductive material, e.g., aluminum of which the surface is anodically oxidized. Preferably, the electrode plate 36 is a low-resistance conductor or semiconductor of a low Joule heat.

Meanwhile, in order to strengthen a photoresist, the electrode plate 36 is preferably made of a material containing silicon. Thus, the electrode plate 36 is preferably made of silicon or SiC. A gas diffusion space 40 is provided in the electrode support 38. A plurality of gas holes 41 extends downwards from the gas diffusion space 40 to communicate with the gas injection openings 37.

A gas inlet opening 62 is formed in the electrode support 38 to introduce a processing gas into the gas diffusion space 40. A gas supply line 64 is connected to the gas inlet opening 62, and a processing gas supply source 66 is connected to the gas supply line 64. A mass flow controller (MFC) 68 and a closing/opening valve 70 are sequentially provided from the upstream side in the gas supply line 64 (here, an FCN (Flow Control Nozzle) can be used instead of the MFC).

Further, a processing gas containing CₓF_{y} (x is an integer equal to or less than 3 and y is an integer equal to or less than 8), C₄F₈ and O₂ is supplied from the processing gas supply source 66 into the gas diffusion space 40 via the gas supply line 64 to be finally injected into the plasma generation space in a shower shape through the gas holes 41 and the gas injection openings 37. That is, the upper electrode 34 functions as a shower head for supplying the processing gas.

A first high-frequency power supply 48 is electrically connected to the upper electrode 34 via a matching unit 46 and a power supply rod 44. The first high-frequency power supply 48 outputs a high frequency power of 10 MHz or higher, e.g., about 60 MHz. The matching unit 46 matches a load impedance to an internal (or output) impedance of the first high-frequency power supply 48, and serves to render the output impedance of the first high-frequency power supply 48 and the load impedance be seemingly matched to each other when a plasma is generated in the chamber 10. An output terminal of the matching unit 46 is connected to the top end of the power supply rod 44.

Meanwhile, a variable DC power supply 50, as well as the first high-frequency power supply 48, is electrically connected to the upper electrode 34. The variable DC power supply 50 may be a bipolar power source. Specifically, the variable DC power supply 50 is connected to the upper electrode 34 via the matching unit 46 and the power supply rod 44. The power feed of the variable DC power supply 50 can be controlled by an on/off switch 52. The polarity, current and voltage of the variable DC power supply 50 and the on/off operation of the on/off switch 52 are controlled by a controller 51.

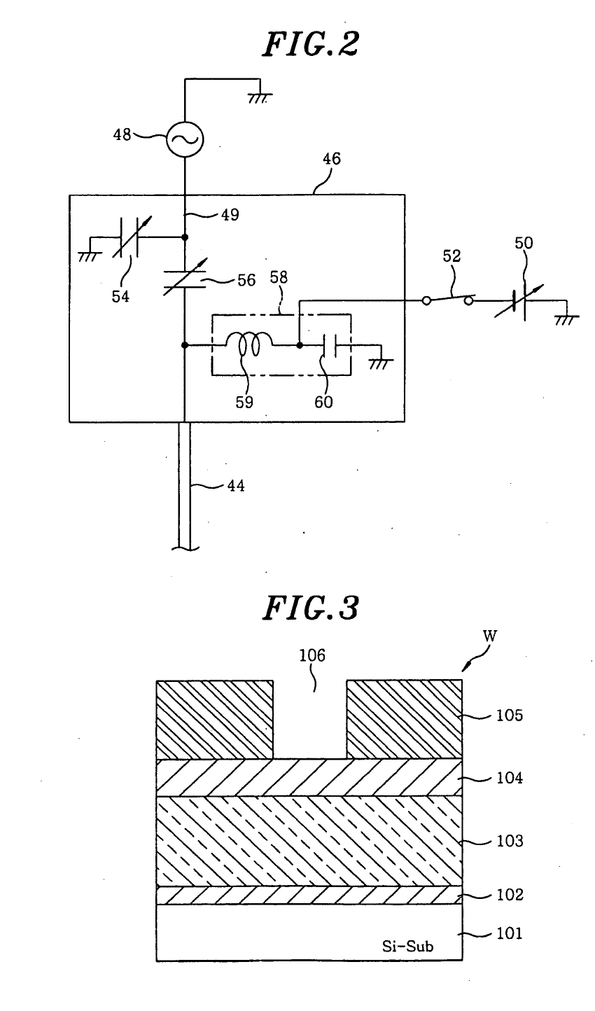

As shown in FIG. 2, the matching unit 46 has a first variable capacitor 54 and a second variable capacitor 56, and functions as described above by using the first and second variable capacitors 54 and 56. The first variable capacitor 54 is branched from a power feed line 49 of the first high-frequency power supply 48, and the second variable capacitor 56 is provided at a downstream side of the branching point in the power feed line 49. Further, a filter 58 is provided in the matching unit 46 to trap a high frequency (e.g., 60 MHz) from the first high-frequency power supply 48 and a high frequency (e.g., 2 MHz) from a second high-frequency power supply to be described later, thus allowing a DC voltage current (hereinafter, referred to as “DC voltage”) to be efficiently supplied to the upper electrode 34. That is, the variable DC power supply 50 is connected through the filter 58 to the power feed line 49. The filter 58 includes a coil 59 and a capacitor 60, and the high frequency from the first high-frequency power supply 48 and the high frequency from the second high-frequency power supply are trapped by the coil 59 and the capacitor 60.

A cylindrical ground conductor 10a extends upwards from a sidewall of the chamber 10 to be located at a position higher than the upper electrode 34. The ceiling wall of the cylindrical ground conductor 10a is electrically insulated from the power supply rod 44 by a tubular insulation member 44a.

The second high-frequency power supply 90 is electrically connected through a matching unit 88 to the susceptor 16 serving as the lower electrode. When a high-frequency power is supplied from the second high-frequency power supply 90 to the susceptor 16, ions are attracted to the semiconductor wafer W. The second high-frequency power supply 90 outputs a high frequency power of a range from 300 KHz to 13.56 MHz, e.g., 2 MHz. The matching unit 88 matches a load impedance to an internal (or output) impedance of the second high-frequency power supply 90, and renders the internal impedance of the second high-frequency power supply 90 and the load impedance be seemingly matched to each other when a plasma is generated in the chamber 10.

A low pass filter (LPF) 92 is electrically connected to the upper electrode 34 for passing the high frequency (e.g., 2 MHz) from the second high-frequency power supply 90 to the ground, without allowing the high frequency (e.g., 60 MHz) from the first high-frequency power supply 48 to pass therethrough. Although the LPF 92 preferably includes an LR filter or an LC filter, it may include a single conducting wire capable of applying sufficiently high reactance to the high frequency (60 MHz) from the first high-frequency power supply 48. Meanwhile, electrically connected to the susceptor 16 is a high pass filter (HPF) 94 for passing the high frequency (60 MHz) from the first high-frequency power supply 48 to the ground.

A gas exhaust port 80 is provided in the bottom of the chamber 10, and a gas exhaust unit 84 is connected to the gas exhaust port 80 through a gas exhaust line 82. The gas exhaust unit 84 has a vacuum pump such as a turbo-molecular pump, and can depressurize the inside of the chamber 10 to a desired vacuum level. Further, a loading/unloading port 85, through which the semiconductor wafer W is loaded and unloaded, is provided in the sidewall of the chamber 10. The loading/unloading port 85 can be opened and closed by a gate valve 86.

Further, a deposition shield 11 is detachably installed at the inner wall of the chamber 10 so as to prevent etching byproducts (deposits) from being attached to the chamber 10. That is, the deposition shield 11 serves as a chamber wall. The deposition shield 11 is also provided on the outer surface of the inner wall member 26. A gas exhaust plate 83 is provided at a lower portion of the chamber 10 between the deposition shield 11 installed at the inner wall of the chamber 10 and the deposition shield 11 disposed at the inner wall member 26. The deposition shield 11 and the gas exhaust plate 83 can be appropriately formed by covering an aluminum material with ceramic such as Y₂O₃.

Further, a conductive member (GND block) 91 DC-connected to the ground is provided to a portion of the deposition shield 11 forming the chamber inner wall at a height position substantially identical with the height of the wafer W. With this configuration, an abnormal discharge can be prevented.

Each component of the plasma etching apparatus is connected to and controlled by a control unit (for controlling the whole components) 95. Further, a user interface 96 is connected to the control unit 95, wherein the user interface 96 includes, e.g., a keyboard for a process manager to input a command to operate the plasma processing apparatus, a display for showing an operational status of the plasma processing apparatus and the like.

Moreover, connected to the control unit 95 is a storage unit 97 for storing therein, e.g., control programs to be used in realizing various processes, which are performed in the plasma processing apparatus under the control of the control unit 95 and programs or recipes to be used in operating each component of the plasma processing apparatus to carry out processes in accordance with processing conditions. The recipes can be stored in a hard disk or a semiconductor memory, or can be set at a certain position of the storage unit 97 while being recorded on a portable storage medium such as a CDROM, a DVD and the like.

When a command or the like is received from the user interface 96, the control unit 95 retrieves a necessary recipe from the storage unit 97 and executes the recipe. Accordingly, a desired process is performed in the plasma processing apparatus under the control of the control unit 95.

Hereinafter, there will be described a plasma etching method in accordance with a first embodiment of the present invention, which is performed by the plasma etching apparatus having the aforementioned configuration.

Here, a semiconductor wafer W to be processed has an etching stopper film 102, an etching target film 103, a bottom anti-reflection coating (BARC) film 104 and a patterned photoresist film 105 that are sequentially formed on a Si substrate 101 as shown in FIG. 3.

The etching stopper film 102 is, e.g., an SiC film. The etching target film 103 as an interlayer insulating film is, e.g., an SiO₂ film or a Low-k film. The BARC film 104 is, e.g., an organic film, and its thickness is about 80 nm. The photoresist film 105 is, e.g., an ArF resist of which thickness is about 120 nm.

In a plasma etching processing, the gate valve 86 is first opened, and the semiconductor wafer W having the above-described configuration is loaded into the chamber 10 through the loading/unloading port 85 to be mounted on the susceptor 16. Then, a processing gas for etching the BARC film 104 is supplied from the processing gas supply source 66 into the gas diffusion space 40 at a predetermined flow rate to be then supplied into the chamber 10 via the gas holes 41 and the gas injection openings 37. While the processing gas being supplied into the chamber 10, the chamber 10 is evacuated by the gas exhaust unit 84 so that the internal pressure of the chamber 10 is maintained at a set value within a range from, e.g., about 0.1 to 150 Pa. Further, a susceptor temperature is set to be in a range from about 0 to 40° C.

After the processing gas for the etching is introduced into the chamber 10, a high frequency power for plasma generation is applied from the first high-frequency power supply 48 to the upper electrode 34 at a specific power level, and, at the same time, a high frequency power for ion attraction is applied from the second high-frequency power supply 90 to the susceptor 16, i.e., the lower electrode, at a specified power level. Further, a DC voltage is applied from the variable DC power supply 50 to the upper electrode 34. Moreover, a DC voltage is applied from the DC power supply 22 to the electrode 20 of the electrostatic chuck 18, so that the semiconductor wafer W is firmly fixed on the susceptor 16.

The processing gas injected through the gas injection openings 37 formed in the electrode plate 36 of the upper electrode 34 is converted into a plasma by a glow discharge generated between the upper electrode 34 and the susceptor 16 serving as the lower electrode by the high frequency powers applied thereto. By radicals or ions generated from the plasma, a surface to be processed of the semiconductor wafer W is etched.

Since the high frequency power within a high frequency range (e.g., 10 MHz or higher) is applied to the upper electrode 34, the plasma can be generated at a high density in a desirable state. Accordingly, it is possible to form a high-density plasma even under a lower pressure condition.

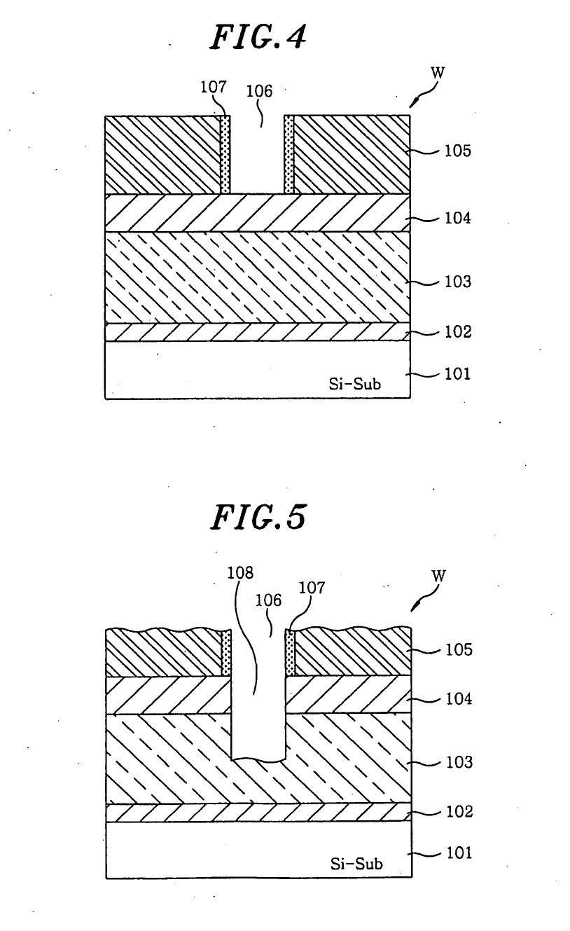

In the present embodiment, when the BARC film 104 and the etching target film 103 are etched, an opening size of an opening 106 of the photoresist film 105 is reduced. To be specific, when the plasma etching is performed, CF-based deposits 107 are deposited on the wall of the opening 106 of the photoresist film 105 which is formed by the photolithography process, thereby reducing the opening 106, as illustrated in FIG. 4. As a consequence, the etching hole 108 of the etching target film 103 and the BARC film 104 is miniaturized, as can be seen from FIG. 5.

In order to reduce the opening size of the opening 106 formed in the photoresist film 105 by the plasma etching by depositing the CF-based deposits on the inner wall of the opening 106, the deposition of the deposits can be effectively controlled by simultaneously using CF-based gas having a high deposition effect, typically, CF₄ gas, and CHF-based gas having a high scavenge effect, for example CH₂F₂ gas.

However, when the ArF photoresist film is used as the photoresist film, if the opening 106 is formed as a hole pattern of small pitch, cracks are generated between the hole patterns due to a low strength of the ArF photoresist film. Therefore, even if the opening size of the opening 106 is reduced by using the processing gas, the cracks cannot be repaired and, thus, the amount of the residual ArF resist becomes insufficient in the portions where the cracks are generated. Accordingly, base wiring patterns are damaged, and this may cause a short-circuit. In addition, when the above processing gas is used, a long period of time is needed to reduce the pattern to a desired dimension, resulting in a decrease in a throughput.

To that end, in the present embodiment, the processing gas contains CF-based gas having a high concentration of C, i.e., CₓF_{y} gas, in addition to CF₄ gas and CH₂F₂ gas. To be specific, there is used CₓF_{y} gas satisfying the condition of x/y≧0.5. By using CₓF_{y} gas having a high concentration of C, the deposits can be evenly formed on the surface of the ArF photoresist film and, also, the amount of deposits increases. Accordingly, the thickness of the photoresist film 105 can be increased and, also, the cracks can be repaired. As a consequence, it is possible to prevent the short-circuit in the wiring caused due to any insufficient amount of residual ArF photoresist film developed locally. Besides, since the deposition is facilitated by using the CₓF_{y} gas, it is possible to shorten time needed to reduce the opening 106 to a desired dimension, thereby improving a throughput.

The above effects obtained by adding CₓF_{y} gas to CF₄ gas and CH₂F₂ gas can be further improved by applying a DC voltage from the variable DC power supply 50 to the upper electrode 34 during the plasma etching. Namely, the above effects can be notably enhanced by adding CₓF_{y} gas and also by applying a DC voltage.

This will be described in further detail.

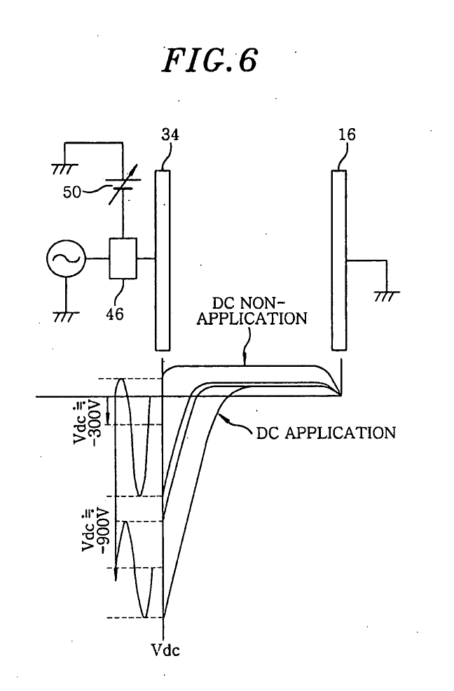

Polymers are attached at the upper electrode 34 during the prior etching process, particularly, during an etching process in which a high frequency power of a low level is applied to the upper electrode 34. If a proper DC voltage is applied to the upper electrode 34 when performing an etching process, a self bias voltage V_{dc} of the upper electrode 34 can be made higher, that is, the absolute value of the V_{dc} at the surface of the upper electrode 34 can be increased, as shown in FIG. 6. As a result, the polymers attached at the upper electrode 34 are sputtered by the applied DC voltage and are supplied to the semiconductor wafer W to be deposited on the photoresist film 105. The polymer deposition effect obtained by the DC voltage application and the aforementioned deposition effect obtained by the processing gas make the opening size of the opening 106 be reduced with a high throughput, and also facilitate the repair of cracks. Consequently, the short-circuit can be further prevented.

As for CₓF_{y} gas satisfying the condition of x/y≧0.5, it is possible to use at least one species selected from the group consisting of C₄F₈ gas, C₅F₈ gas and C₄F₆ gas. The flow rates of these gases are properly changed depending on gas types. Among these gases, C₅F₈ gas, which is comparatively effective and suitable for mass production, is preferred and a flow rate thereof is preferably in a range from about 5 to 10 mL/min (sccm). The effects of these gases increase as the concentration of C therein increases. In the case of C₄F₈ gas having a lower concentration of C compared to C₅F₈ gas, a flow rate is preferably in a range from about 5 to 40 mL/min (sccm). In the case of C₄F₆ gas having a highest concentration of C, desired effects may be obtained at a comparatively small flow rate thereof.

Preferably, the flow rate of CF₄ gas is in a range from about 100 to 200 mL/min (sccm), and the flow rate of CH₂F₂ gas is in a range from about 5 to 30 mL/min (sccm). The processing gas may contain CF₄ gas, CH₂F₂ gas and CₓF_{y} gas, or an inert gas such as Ar gas or the like can be added thereto.

In order to obtain the above effects, a DC voltage applied from the variable DC power supply 50 to the upper electrode 34 is preferably in a range from about −500 V and −1500 V.

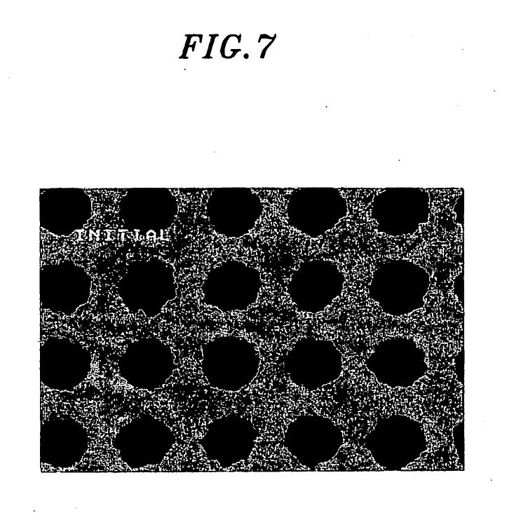

Below, experimental results for investigating the effects of the etching method in accordance with the embodiment of the present invention will be described. Here, a substrate to be processed was manufactured by sequentially forming, on a porous low-k film as an etching target film, an organic BARC film and an ArF resist film as an etching mask thereon. FIG. 7 is a picture obtained by a scanning electron microscope (SEM) shows an initial state of an ArF resist film before performing plasma etching thereto. Herein, it is recognizable that cracks were generated at several opening patterns.

The substrate thus manufactured was loaded into the apparatus in FIG. 1 to be subjected to a plasma etching process under a condition A of the present embodiment and a comparative condition B.

### <Condition A>

Pressure inside chamber: 13.3 Pa (100 mT)
Upper high frequency power: 500 W
Lower high frequency power: 400 W
DC voltage: −1000 V

### Processing Gas and Flow Rate:

CF₄=150 mL/min (sccm)

CH₂F₂=20 mL/min (sccm)

C₅F₈=7 mL/min (sccm)

### Magnetic Field:

Center=15 T

Edge=40 T

### Temperature:

Upper electrode and wafer=60° C.

Susceptor=20° C.

### <Condition B>

Pressure inside chamber: 13.3 Pa (100 mT)
Upper high frequency power: 500 W
Lower high frequency power: 400 W
DC voltage: −500 V

### Processing Gas and Flow Rate:

CF₄=150 mL/min (sccm)

CH₂F₂=20 mL/min (sccm)

### Magnetic Field:

Center=15 T

Edge=40 T

### Temperature:

Upper electrode and wafer=60° C.

Susceptor=20° C.

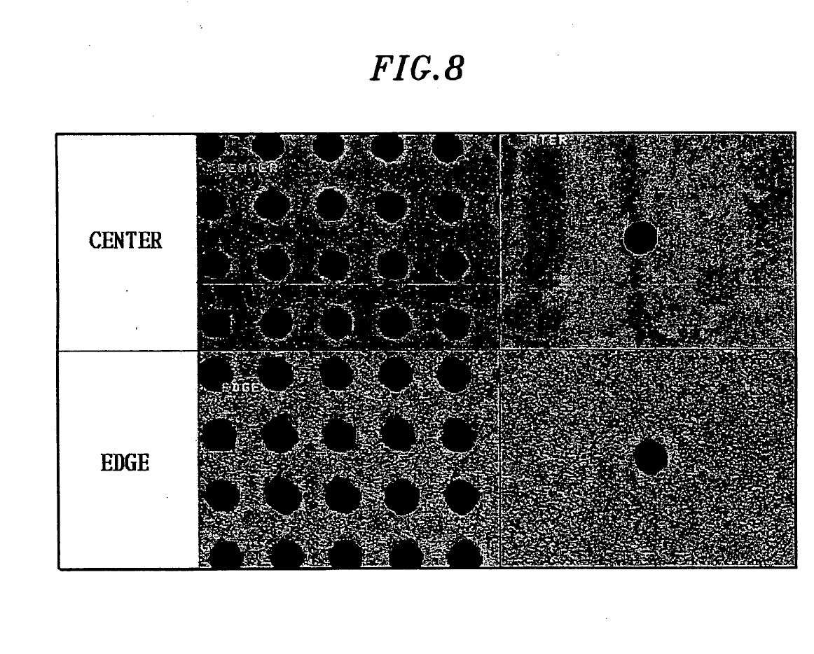

When the etching process was performed under the condition A of the present embodiment, an opening size of a hole-shaped opening of the photoresist film was decreased from about 140 nm to a target dimension of 110 nm after performing the etching process for about 10 seconds. Further, cracks in the surface of the etched photoresist film were repaired, as illustrated in the SEM picture of FIG. 8. In addition, a thickness of the residual resist film was about 230 nm in the center and about 220 nm in the edge.

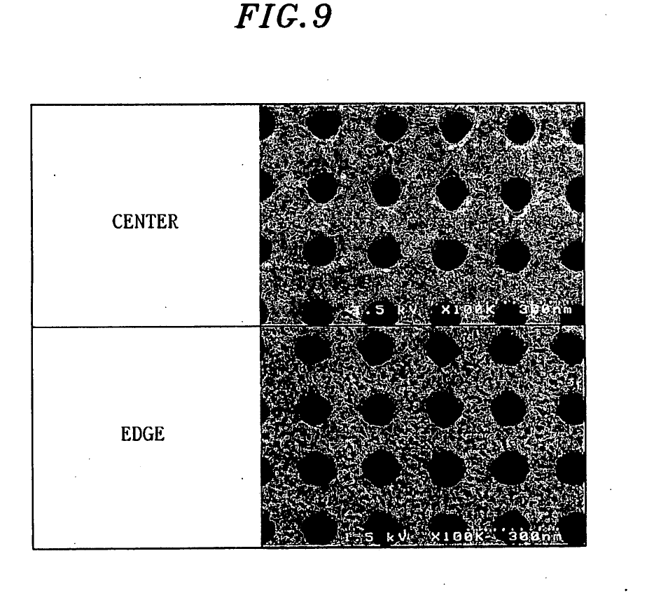

Meanwhile, when the etching process was performed under the comparative condition B, the opening size of the hole-shaped opening of the photoresist film was decreased from about 140 nm to a target dimension of 110 nm after performing the etching process for about 40 seconds. Further, the initial cracks were remaining, as can be seen from the SEM picture of FIG. 9. Besides, a thickness of the residual resist film was about 220 nm in the center and about 218 nm in the edge.

From the above result, it was found that when the etching was performed under the condition of the present embodiment, the cracks remaining in the ArF resist film were repaired and, also, time needed to reduce the hole-shaped opening was shortened, compared to when the etching was performed under the comparative condition. Consequently, by performing the etching under the condition of the embodiment, an opening size of an opening can be reduced while ensuring a high throughput. Moreover, it was also found that the larger amount of the photoresist film remained when the etching was performed under the condition of the present embodiment.

Hereinafter, a plasma etching method in accordance with a second embodiment of the present invention will be described.

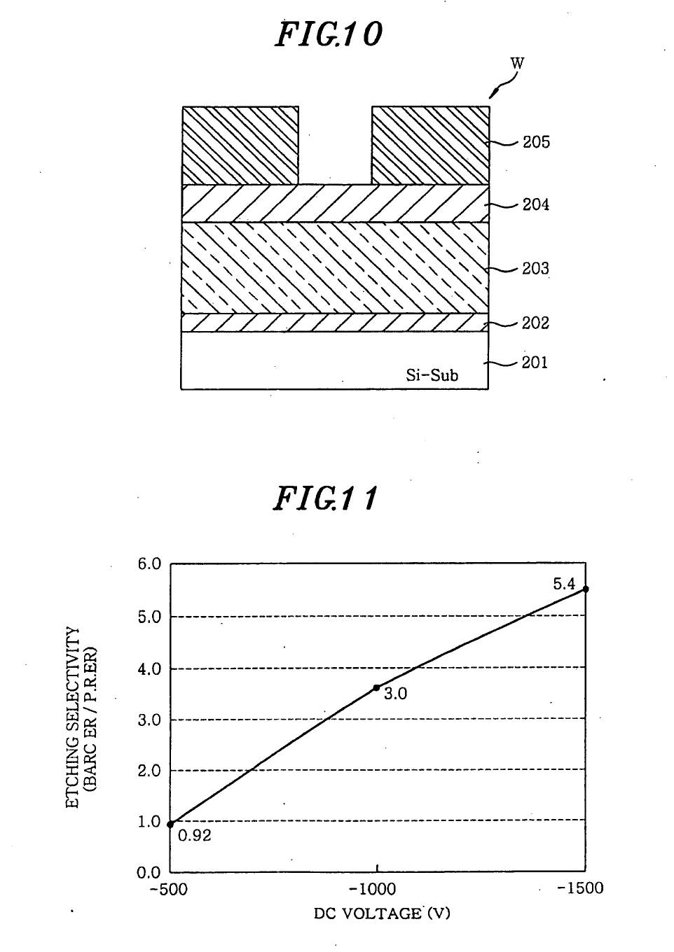

In the second embodiment, a semiconductor wafer W shown in FIG. 10 is used as a substrate to be processed, the semiconductor having an etching stopper film 202, an etching target film 203, an organic BARC film 204 and a patterned photoresist film 205 which are sequentially formed on a Si substrate 201. Before etching the etching target film 203, the organic BARC film 204 is etched by using the photoresist film 205 as a mask.

When the etching is performed, the organic BARC film 204 needs to be etched with a high etching selectivity to the photoresist film 205 in view of ensuring a sufficient amount of a residual mask film. However, the organic BARC film 204 has a similar composition as that of the photoresist film 205 such as an ArF photoresist film or the like. Therefore, when the organic BARC film 204 is etched, the photoresist film 205 is etched at substantially the same etching rate. Accordingly, the amount of the residual mask film becomes insufficient.

Therefore, in the present embodiment, the organic BARC film 204 is etched with a high selectivity to the photoresist film 205 by applying a DC voltage from the variable DC power supply 50 to the upper electrode 34, as will be described later.

To be specific, the gate valve 86 is first opened, and the semiconductor wafer W having the above-described configuration is loaded into the chamber 10 through the loading/unloading port 85 to be mounted on the susceptor 16. Then, a processing gas for etching the BARC film 104 is supplied from the processing gas supply source 66 into the gas diffusion space 40 at a predetermined flow rate to be then supplied into the chamber 10 via the gas holes 41 and the gas injection openings 37. While the processing gas being supplied into the chamber 10, the chamber 10 is evacuated by the gas exhaust unit 84 so that the internal pressure of the chamber 10 is maintained at a set value within a range from, e.g., about 0.1 to 150 Pa. Further, a susceptor temperature is set to be in a range from about 0 to 40° C.

After the processing gas for the etching is introduced into the chamber 10, a high frequency power for plasma generation is applied from the first high-frequency power supply 48 to the upper electrode 34 at a specific power level, and, at the same time, a high frequency power for ion attraction is applied from the second high-frequency power supply 90 to the susceptor 16, i.e., the lower electrode, at a specified power level. Further, a DC voltage is applied from the variable DC power supply 50 to the upper electrode 34. Moreover, a DC voltage is applied from the DC power supply 22 to the electrode 20 of the electrostatic chuck 18, so that the semiconductor wafer W is firmly fixed on the susceptor 16.

The processing gas injected through the gas injection openings 37 formed in the electrode plate 36 of the upper electrode 34 is converted into a plasma by a glow discharge generated between the upper electrode 34 and the susceptor 16 serving as the lower electrode by the high frequency powers applied thereto. By radicals or ions generated from the plasma, a surface to be processed of the semiconductor wafer W is etched.

In the present embodiment, when the etching process is performed, a DC voltage is applied from the variable DC power supply 50 to the upper electrode 34. By applying a DC voltage, the polymers attached to the upper electrode 34 are sputtered by the applied DC voltage and are supplied to the semiconductor wafer W to be deposited on the photoresist film 205, as in the first embodiment. Accordingly, a thickness of the photoresist film 205 can be increased and, thus, an etching selectivity of the organic BARC film 204 to the photoresist film 205 can be increased. Although the etching selectivity increases as an absolute value of the applied voltage increases, it is preferable that the applied voltage is in a range from about −1000 V to −1500 V so that the etching selectivity greater than or equal to about 3.0 can be obtained in such a range.

Although the processing gas used in the present embodiment may be a conventionally used gas, it is preferable to use CF₄ gas, CH₂F₂ gas and CₓF_{y} gas satisfying the condition of x/y≧0.5, as in the first embodiment. As for the CₓF_{y} gas satisfying the condition of x/y≧0.5, there can be used at least one species selected among C₄F₈ gas, C₅F₈ gas and C₄F₆ gas. Among them, it is preferable to use C₅F₈ gas, and a flow rate thereof is preferably in a range from about 5 to 10 mL/min (sccm). Further, a flow rate of CF₄ gas is preferably in a range from about 100 to 200 mL/min (sccm). Moreover, a flow rate of CH₂F₂ gas is preferably in a range from about 5 to 30 mL/min (sccm). The processing gas may contain CF₄ gas, CH₂F₂ gas and CₓF_{y} gas, or an inert gas such as Ar or the like may be added thereto.

When the organic BARC film 204 is plasma-etched by the processing gas used in the first embodiment while using an ArF resist film as a mask as in this embodiment, it is possible to obtain the effect of etching the BARC film with a high selectivity by controlling a DC voltage applied to the upper electrode 34, in addition to the effect of the first embodiment which can reduce an opening size of an opening of the ArF resist film with a high throughput while repairing cracks.

Further, when the organic BARC film is plasma-etched by using the ArF photoresist film as a mask, the etching can be performed in two steps. In a first step, the opening size of the opening of the ArF resist film is reduced with a high throughput while repairing cracks under the condition in which the opening of the photoresist film of the first embodiment can be reduced. Next, in a second step, the organic BARC film is etched under the condition in which the organic BARC film of the second embodiment can be etched with a high etching selectivity to the ArF photoresist film.

Hereinafter, experimental results for investigating the effects of the etching method in accordance with the second embodiment of the present invention will be described.

Here, a substrate to be processed was manufactured by sequentially forming, on a porous low-k film as an etching target film, an organic BARC film and an ArF resist film as an etching mask film thereon. The substrate thus manufactured was loaded into the apparatus in FIG. 1 to be subjected to a plasma etching process under the following condition:

Pressure inside chamber: 13.3 Pa (100 mT)
Upper high frequency power: 500 W
Lower high frequency power: 400 W
DC voltage: −500 V to −1500 V

### Processing Gas and Flow Rate:

CF₄=150 mL/min (sccm)

CH₂F₂=20 mL/min (sccm)

C₅F₈=7 mL/min (sccm)

### Magnetic Field:

Center=15 T

Edge=40 T

### Temperature:

Upper electrode and wafer=60° C.

Susceptor=20° C.

FIG. 11 shows the result of etching performed under the above condition. FIG. 11 also illustrates a relationship between a DC voltage applied to the upper electrode 34 which is presented at x-axis and an etching selectivity of the organic BARC film to the ArF resist film which is presented at y-axis. As depicted in FIG. 11, as the applied DC voltage (absolute value) increases, the etching selectivity increases. That is, it was found that the organic BARC film was etched with a high etching selectivity of about 3.0 to 5.4 when the applied DC voltage was about −1000V and −1500V.

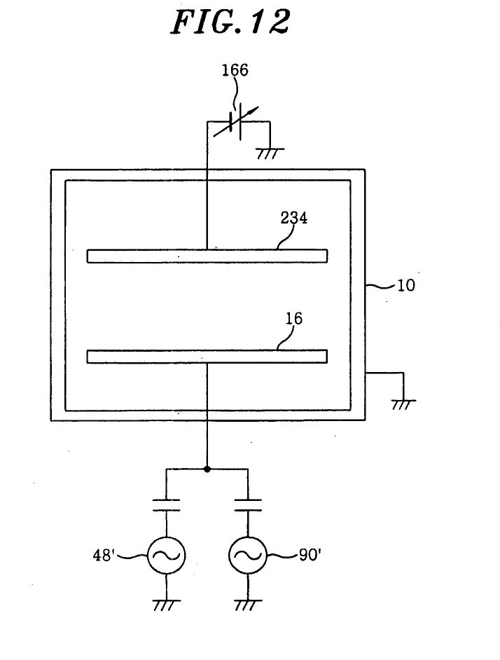

The present invention can be modified without being limited to the above embodiments. Further, the apparatus to which the present invention is applied is not limited to the one shown in FIG. 1. For example, as shown in FIG. 12, it is possible to use a plasma etching apparatus of a type in which dual frequency powers are applied to the susceptor 16 as a lower electrode. In this type of apparatus, a high frequency power of, e.g., about 60 MHz for plasma generation is applied from a first high frequency power supply 48′ to the susceptor 16 serving as the lower electrode, and a second high frequency power of, e.g., about 2 MHz for ion attraction is concurrently applied from a second high frequency power supply 90′ to the susceptor 16. The effects of the above embodiments can be obtained by connecting a variable DC power supply 166 to an upper electrode 234 and applying a DC voltage thereto, as illustrated in FIG. 12.

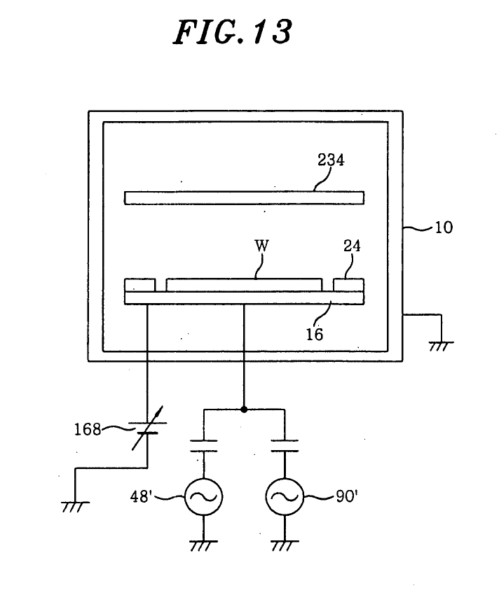

In this case, a DC voltage can be applied to the susceptor 16 by connecting a DC power supply 168 to the susceptor 16 as the lower electrode, as illustrated in FIG. 13.

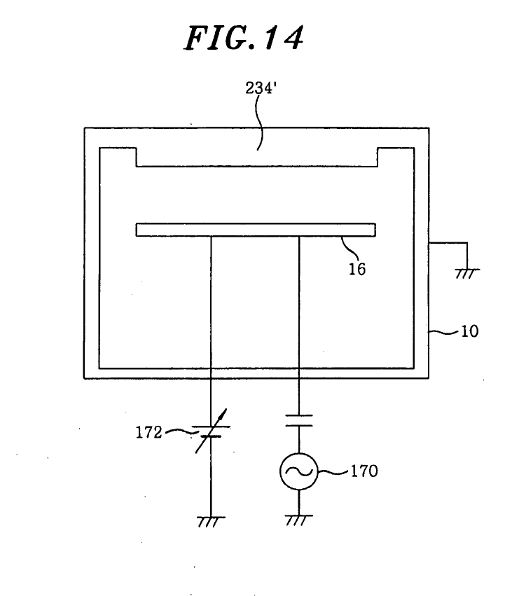

Further, as illustrated in FIG. 14, it is also possible to use a plasma etching apparatus of a type in which an upper electrode 234′ is grounded via the chamber 10, and the susceptor 16 as the lower electrode is connected to a high frequency power supply 170. In this configuration, a high frequency power of, e.g., about 13.56 MHz, for plasma generation is applied from the high frequency power supply 170 to the susceptor 16 as the lower electrode. Further, a variable DC power supply 172 is connected to the susceptor 16 as the lower electrode and applies a predetermined DC voltage to the susceptor 16, whereby the effects of the above embodiments can be obtained.

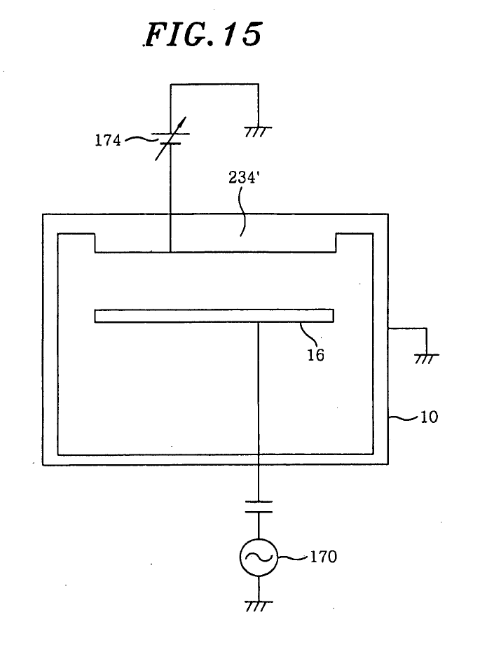

In addition, as shown in FIG. 15, it is possible to use an etching apparatus of a type in which the upper electrode 234′ is grounded via the chamber 10, and the susceptor 16 as a lower electrode is connected to the high frequency power supply 170, as FIG. 14. In this configuration, a high frequency power for plasma generation is applied from the high frequency power supply 170 to the susceptor 16 as a lower electrode. In such an etching apparatus, a variable DC power supply 174 can be applied to the upper electrode 234′.

While the invention has been shown and described with respect to the embodiments, it will be understood by those skilled in the art that various changes and modification may be made without departing from the scope of the invention as defined in the following claims.

What is claimed is:

1. A plasma etching method for plasma etching an etching target film by using a photoresist film as a mask, the plasma etching method comprising:
loading a target object to be processed into a processing chamber where an upper and a lower electrode are provided to face each other, the target object having the etching target film and the photoresist film in which an opening is formed;
introducing into the processing chamber a processing gas containing CF₄ gas, CH₂F₂ gas and CₓF_{y} gas, wherein x/y≧0.5;
generating a plasma of the processing gas by applying a high frequency power to at least one of the upper and the lower electrode; and
by the plasma, etching the etching target film through the opening formed in the photoresist film while reducing the opening size the opening.

2. The plasma etching method of claim 1, wherein the CₓF_{y} gas includes at least one species selected from the group consisting of C₄F₈ gas, C₅F₈ gas and C₄F₆ gas.

3. The plasma etching method of claim 2, wherein the CₓF_{y} gas is C₅F₈ gas, and a flow rate thereof is in the range from 5 to 10 sccm.

4. The plasma etching method of claim 1, wherein the target object has an organic bottom anti-reflection coating film between the photoresist film and the etching target film.

5. A plasma etching method for plasma etching an etching target film by using a photoresist film as a mask, the plasma etching method comprising:
loading a target object to be processed into a processing chamber where an upper and a lower electrode are provided to face each other, the target object having the etching target film and the photoresist film in which an opening is formed as an etching pattern;
introducing into the processing chamber a processing gas containing CF₄ gas, CH₂F₂ gas and CₓF_{y} gas, wherein x/y≧0.5;
generating a plasma of the processing gas by applying a high frequency power to at least one of the upper and the lower electrode;
applying a DC voltage to one of the upper and the lower electrode for a predetermined time period while the plasma is formed; and
by the plasma, etching the etching target film through the opening formed in the photoresist film while reducing the opening size of the opening.

6. The plasma etching method of claim 5, wherein the DC voltage is in the range from −500 V to −1500 V.

7. The plasma etching method of claim 5, wherein the CₓF_{y} gas includes at least one species selected from the group consisting of C₄F₈ gas, C₅F₈ gas and C₄F₆ gas.

8. The plasma etching method of claim 7, wherein the CₓF_{y} gas is C₅F₈ gas, and a flow rate thereof is in the range from 5 to 10 sccm.

9. The plasma etching method of claim 5, wherein the target object has an organic bottom anti-reflection coating film between the photoresist film and the etching target film.

10. A plasma etching method for plasma-etching an organic bottom anti-reflection coating film and an etching target film by using a photoresist film as a mask in a target object to be processed which is manufactured by sequentially forming, on the etching target film, the organic bottom anti-reflection coating film and the photoresist film formed thereon with an opening therein, the plasma etching method comprising:
loading the target object into a processing chamber where an upper and a lower electrode are provided to face each other;
introducing into the processing chamber a processing gas;
generating a plasma of the processing gas by applying a high frequency power to at least one of the upper and the lower electrode; and
applying a DC voltage to one of the upper and the lower electrode for a predetermined time period while the plasma is formed so that the organic bottom anti-reflection coating film is etched with a selectivity greater than or equal to a predetermined value to the photoresist film.

11. The plasma etching method of claim 10, wherein the DC voltage is in the range from −1000 V to −1500 V.

12. The plasma etching method of claim 10, wherein the processing gas contains CF₄ gas, CH₂F₂ gas, CₓF_{y} gas, wherein x/y≧0.5.

13. A plasma etching method for plasma-etching an organic bottom anti-reflection coating film and an etching target film by using a photoresist film as a mask in a target object to be processed which is manufactured by sequentially forming, on the etching target film, the organic bottom anti-reflection coating film and the photoresist film formed thereon with an opening therein serving as an etching pattern, the plasma etching method comprising:
loading the target object into a processing chamber where an upper and a lower electrode are provided to horizontally face each other;
introducing into the processing chamber a processing gas containing CF₄ gas, CH₂F₂ gas and CₓF_{y} gas, wherein x/y≧0.5;
generating a plasma of the processing gas by applying a high frequency power to at least one of the upper and the lower electrode;
applying a DC voltage to one of the upper and the lower electrode for a first time period while the plasma is formed so that the opening size of the opening formed in the photoresist film is reduced; and then applying a DC voltage to one of the upper and the lower electrode for a second time period while the plasma is formed so that the organic bottom anti-reflection coating film is etched with a selectivity greater than or equal to a predetermined value to the photoresist film.

14. The plasma etching method of claim 13, wherein the DC voltage applied during the first time period is in the range from −500 V to −1500 V, and the DC voltage applied during the second time period is in the range from −1000 V to −1500 V.

15. The plasma etching method of claim 12, the CₓF_{y} gas includes at least one species selected from the group consisting of C₄F₈ gas, C₅F₈ gas and C₄F₆ gas.

16. The plasma etching method of claim 15, wherein the CₓF_{y} gas is C₅F₈ gas, and a flow rate thereof is in the range from 5 to 10 sccm.

17. The plasma etching method of claim 13, the CₓF_{y} gas includes at least one species selected from the group consisting of C₄F₈ gas, C₅F₈ gas and C₄F₆ gas.

18. The plasma etching method of claim 17, wherein the CₓF_{y} gas is C₅F₈ gas, and a flow rate thereof is in the range from 5 to 10 sccm.

19. A plasma etching apparatus comprising:
a vacuum-evacuable processing chamber having therein a target object to be processed having a photoresist film and an etching target film;
an upper and a lower electrode disposed in the processing chamber to face each other;
a gas introduction mechanism for introducing into the processing chamber a processing gas containing CF₄ gas, CH₂F₂ gas and CₓF_{y} gas, wherein x/y≧0.5;
a high frequency power supply unit for generating a plasma of the processing gas by applying a high frequency power to at least one of the upper and the lower electrode; and
a control unit for controlling at least one of the gas introduction mechanism and the high frequency power supply unit so that, by the plasma, an etching target film is etched through an opening formed in the photoresist film while reducing the opening size of the opening.

20. A plasma etching apparatus comprising:
a vacuum-evacuable processing chamber having therein a target object to be processed having a photoresist film and an etching target film;
an upper and a lower electrode disposed in the processing chamber to face each other;
a gas introduction mechanism for introducing into the processing chamber a processing gas containing CF₄ gas, CH₂F₂ gas and CₓF_{y} gas, wherein x/y≧0.5;
a high frequency power supply unit for generating a plasma of the processing gas by applying a high frequency power to at least one of the upper and the lower electrode;
a DC power supply unit for applying a DC voltage to one of the upper and the lower electrode; and
a control unit for controlling the DC power supply unit, at least one of the gas introduction mechanism and the high frequency power supply unit so that, by the plasma, an etching target film is etched through an opening formed in the photoresist film while reducing the opening size of the opening.

21. A plasma etching apparatus for plasma-etching an organic bottom anti-reflection coating film and an etching target film by using a photoresist film as a mask in a target object to be processed which is manufactured by sequentially forming, on the etching target film, the organic bottom anti-reflection coating film and the photoresist film thereon, the plasma etching apparatus comprising:
a vacuum-evacuable processing chamber having therein the target object;
an upper and a lower electrode disposed in the processing chamber to face each other;
a gas introduction mechanism for introducing a processing gas into the processing chamber;
a high frequency power supply unit for generating a plasma of the processing gas by applying a high frequency power to at least one of the upper and the lower electrode;
a DC power supply unit for applying a DC voltage to one of the upper and the lower electrode; and
a control unit for controlling the DC power supply unit so that the organic bottom anti-reflection coating film is etched with a selectivity greater than or equal to a predetermined value to the photoresist film.

22. A plasma etching apparatus for plasma-etching an organic bottom anti-reflection coating film and an etching target film by using a photoresist film as a mask in a target object to be processed which is manufactured by sequentially forming, on the etching target film, the organic bottom anti-reflection coating film and the photoresist film thereon, the plasma etching apparatus comprising:
a vacuum-evacuable processing chamber having therein the target object;
an upper and a lower electrode disposed in the processing chamber to face each other;
a gas introduction mechanism for introducing into the processing chamber a processing gas containing CF₄ gas, CH₂F₂ gas and CₓF_{y} gas, wherein x/y≧0.5;
a high frequency power supply unit for generating a plasma of the processing gas by applying a high frequency power to at least one of the upper and the lower electrode;
a DC power supply unit for applying a DC voltage to one of the upper and the lower electrode; and
a control unit for controlling the DC power supply unit to apply a DC voltage while plasma is formed such that while the plasma of the processing gas is generated by the high frequency power supply unit, there exists a specific time period during which the opening size of an opening formed in the photoresist film is reduced and a second time period during which the organic bottom anti-reflection coating film is etched with a selectivity greater than a predetermined value to the photoresist film.

23. A storage medium storing therein a computer-executable program for controlling a plasma etching apparatus, wherein, when executed, the program controls the plasma etching apparatus to perform the plasma etching method described in claim 1.

24. A storage medium storing therein a computer-executable program for controlling a plasma etching apparatus, wherein, when executed, the program controls the plasma etching apparatus to perform the plasma etching method described in claim 5.

25. A storage medium storing therein a computer-executable program for controlling a plasma etching apparatus, wherein, when executed, the program controls the plasma etching apparatus to perform the plasma etching method described in claim 10.

26. A storage medium storing therein a computer-executable program for controlling a plasma etching apparatus, wherein, when executed, the program controls the plasma etching apparatus to perform the plasma etching method described in claim 13.
